(19) United States
(12) Patent Application Publication
(10) Pub. No.: US 2025/0321266 A1
(43) Pub. Date: Oct. 16, 2025

(54) Probe head having features to facilitate cooling with liquid-cooled heat exchanger

(71) Applicant: FormFactor, Inc., Livermore, CA (US)

(72) Inventors: January Kister, Portola Valley, CA (US); Mohammad Kazemi, San Jose, CA (US)

(21) Appl. No.: 19/177,067

(22) Filed: Apr. 11, 2025

Related U.S. Application Data
(60) Provisional application No. 63/633,246, filed on Apr. 12, 2024.

(51) Int. Cl. G01R 31/28; G01R 1/073

(52) U.S. Cl. CPC G01R 31/2877; G01R 1/07378

(57) ABSTRACT

Improved heat dissipation in probe heads for testing electrical devices is provided by the use of liquid cooled heat exchanger elements combined with heat conduction features that pass vertically through the printed circuit board of the probe head. In cases where the heat exchanger element(s) are disposed on the DUT-side of the probe head, the heat conduction features are pipes for liquid flow to and from the heat exchanger element(s). In cases where the heat exchanger element(s) are disposed on the top side of the probe head (e.g., on the stiffener), the heat conduction features are solid thermal conduction members configured to increase thermal conduction from the DUT side of the probe head to the top side. The heat exchanger elements can be separate parts, or they can be integrated with probe head components such as the stiffener or the mounting ring.

### CROSS REFERENCE TO RELATED APPLICATIONS

This application claims priority from U.S. Provisional Patent Application 63/633,246 filed Apr. 12, 2024, which is incorporated herein by reference.

### GOVERNMENT SPONSORSHIP

None.

### FIELD OF THE INVENTION

This invention relates to probe heads for making temporary electrical contact to a device under test.

### BACKGROUND

As technology evolves, probe heads for making temporary electrical contact to a device under test (DUT) can become subject to new requirements for which known solutions are inadequate. One example of such new requirements is the requirement to accommodate significant amounts of heat. For example, high performance power chips presently consume 50-150 W and are projected to draw 800 W in the future. Essentially all of that power is dissipated from the device under test as heat, and that heat can create a significant thermal load on the probe head that must be managed to prevent probe head overheating.

Although there is some consideration of dealing with heat in probe heads in the literature, these solutions do not suffice to deal with the above-described problem. For example, in the work of U.S. Pat No. 7,592,821, the primary concern isn't heat dissipation per se. Instead, the concern being addressed is that non-uniform heating of the probe head could cause probe head parts to go out of alignment due to thermal expansion mismatch. So that work doesn't consider the problem of getting a large amount of heat out of the probe head. In the example of US 2024/0027494, a probe head is considered that has a liquid-cooled space transformer. However, a space transformer is a complex and expensive component already subject to numerous design constraints, so modifying it to also act as a liquid-cooled heat exchanger element is unlikely to be a practical solution. Accordingly, it would be an advance in the art to provide improved thermal management for probe heads.

### SUMMARY

To prevent the device under test as well as the testing probe card from overheating we consider liquid-cooled heat exchanger(s) disposed at strategic locations on the probe card. At high power levels, preventing the probe card from overheating is only possible with a heat exchanger. As indicated above, prior solutions did not address the high-power requirements.

With a heat exchanger connected to an external condenser we are able to actively control the heat flux and regulate the temperature of chip or probe card structure. Probes can function as thermal path for transferring heat to heat exchanger. Heat exchangers attached to the bottom of the printed circuit board, space transformer, or guide plates and spacer are more effective for controlling probe card temperature due to shorter thermal path and faster thermal reaction time in removing heat energy hence preventing overheating of the chip or probe card structure.

An important aspect of this work is having thermal conduction features (e.g., solid heat conduction members or liquid flow pipe sections) that pass vertically through the printed circuit board. The main reason for this is that space on the DUT-side of a probe head tends to be extremely limited, mainly by the height of the probes (which can be well under 1 cm). So there is simply no room on the DUT side of the printed circuit board for liquid flow inlets, liquid flow outlets and the like.

But it is also undesirable to try to do all the thermal management on the top side of the printed circuit board. That approach would have the disadvantage of doing nothing to reduce the high thermal resistance between the DUT side and the top side of a conventional probe head. This issue of high thermal resistance is addressed in this work by the above-mentioned thermal conduction features that pass vertically through the printed circuit board.

In cases where the heat exchanger element(s) are disposed on the DUT-side of the probe head, the heat conduction features are pipes for liquid flow to and from the heat exchanger element(s). In cases where the heat exchanger element(s) are disposed on the top side of the probe head (e.g., on the stiffener), the heat conduction features are solid thermal conduction members configured to increase thermal conduction from the DUT side of the probe head to the top side.

The coolant liquid is cooled using an external chiller. The temperature of the heat exchanger is managed using a controller. The controller receives temperature signals from the heat exchanger and commands the chiller to adapt to reach desired temperature at the heat exchanger.

The coolant liquid enters and exits the heat exchanger via designated tubes. There will be a need to accommodate the placement of these tubes in the probe card assembly. These accommodations include having cut off holes in different components of the probe card assembly.

The heat exchangers may be separate components or integrated with existing components of the probe card assembly. For example, the bottom heat exchanger can be integrated with the mounting ring. As another example, the top heat exchanger can be integrated with the stiffener.

The heat exchangers and stiffener are preferably made of materials with good thermal conductivity such copper, aluminum, a copper alloy, an aluminum alloy, etc. That would allow for efficient heat dissipation from the probe card assembly. In addition, the interface between heat exchangers and the components of the probe card assembly is preferably filled with thermal epoxy to minimize thermal contact resistance.

### BRIEF DESCRIPTION OF THE DRAWINGS

FIG. 1 shows a prior art probe head.

FIG. 2 shows a first exemplary embodiment of the invention.

FIGS. 3-4 show variants of the embodiment of FIG. 2.

FIG. 5 shows a second exemplary embodiment of the invention.

FIG. 6. shows a variant of the embodiment of FIG. 5.

FIG. 7. shows a combination of the embodiments of FIGS. 2 and 5.

FIG. 8 shows an embodiment having a stiffener that also acts as a heat exchanger element.

FIG. 9 shows an embodiment having a mounting ring that also acts as a heat exchanger element.

### DETAILED DESCRIPTION

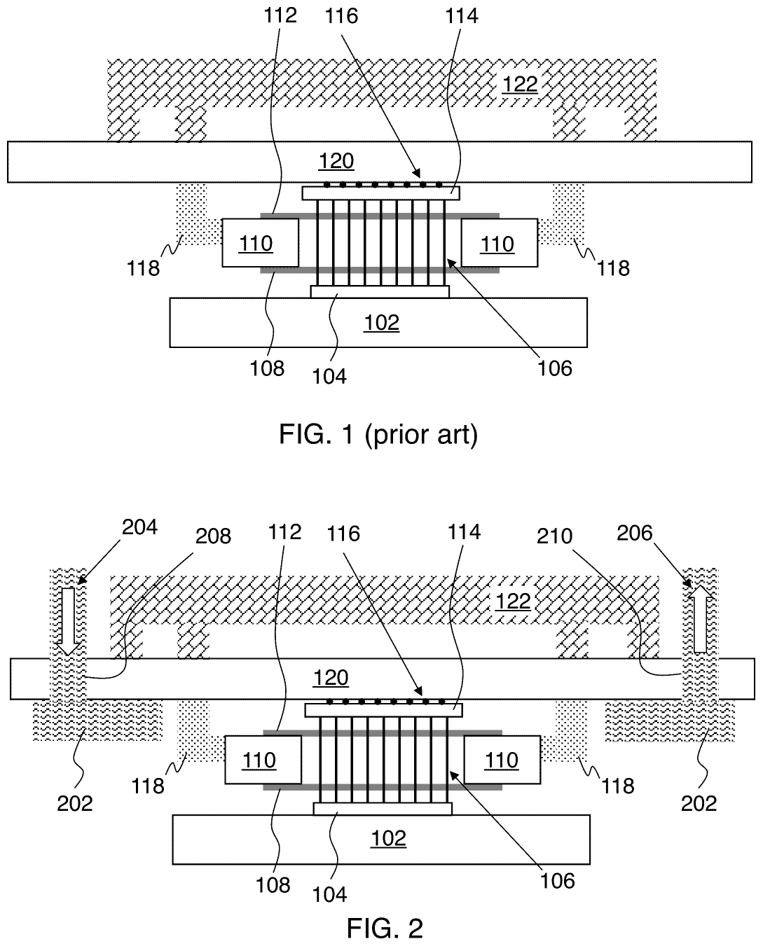

To better appreciate the present invention, it is helpful to first consider a typical prior art probe head, as in the example of FIG. 1. In this example, a device under test (DUT) 104 is held on a chuck 102 for testing using a probe array 106. Probe array 106 passes through upper and lower guide plates (112 and 108 respectively) that define the lateral position of each probe of the probe array. A spacer frame 110 laterally surrounds the probe array and defines a vertical separation of the guide plates. A mounting ring 118 is configured to attach spacer frame 110 to a printed circuit board 120. Electrical connections from probe array 106 to printed circuit board 120 are via space transformer 114 and electrical connections 116 (e.g., a ball-grid array). On the top side of printed circuit board 120, a stiffener 122 is disposed to provide mechanical support. It is sometimes convenient to refer to the combination of guide plates, spacer frame and mounting ring as a probe head assembly.

As indicated above, the main idea of this work is to improve cooling of probe heads with liquid cooled heat exchangers, where at least one heat conduction feature passes through the printed circuit board.

Thus an exemplary embodiment of the invention is a probe head for making temporary electrical contact to a device under test, the probe head comprising:
a printed circuit board having opposite first and second surfaces;
a space transformer disposed on the second surface of the printed circuit board;
a probe array disposed on the space transformer, where probe tips of the probe array face away from the printed circuit board;
at least one liquid-cooled heat exchanger element for dissipating heat received by the probe head from the device under test; and
at least one heat conduction feature configured to pass through the printed circuit board.

The example of FIG. 2 shows a first embodiment of the invention, where the at least one liquid-cooled heat exchanger element 202 is disposed on the second surface of printed circuit board 120 (as shown), and the at least one heat conduction feature includes at least one liquid flow inlet 208 and at least one liquid flow outlet 210 in liquid communication with the at least one liquid-cooled heat exchanger element 202. Liquid flow inlets and outlets 208 and 210 can be made of any materials suitable for fabricating vertical pipes for liquid flow that pass through a printed circuit board. Here 204 and 206 schematically show liquid flows to and from heat exchanger element 202, respectively. Also, although it is not shown in the cross section view of FIG. 2, there is a liquid flow path connecting 202 on the left side of the figure to 202 on the right side of the figure. For example, heat exchanger element 202 could be configured as a hollow rectangle that surrounds mounting ring 118. Practice of the invention does not depend on details of this flow path, so it isn't shown. For example, that flow could be via a conduit or pipe that goes laterally around mounting ring 118.

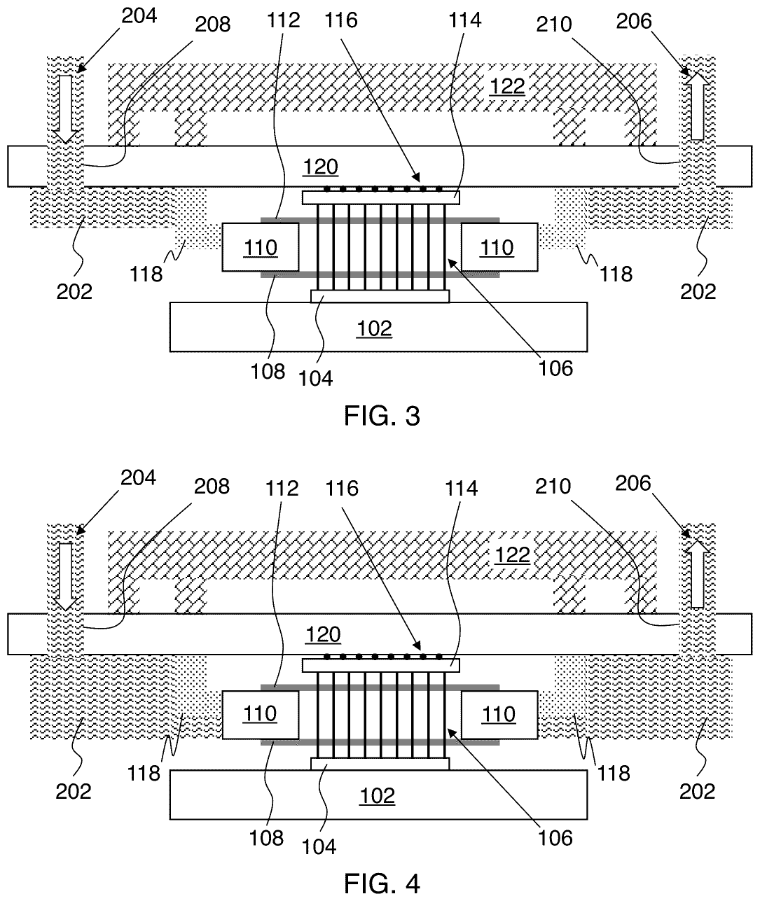

The example of FIG. 3 is similar to the example of FIG. 2, except that here the least one liquid-cooled heat exchanger element 202 is disposed to make direct thermal contact to the mounting ring 118, as shown.

The example of FIG. 4 is similar to the example of FIG. 3, except that here the least one liquid-cooled heat exchanger element 202 is disposed to make direct thermal contact to the spacer frame 110, as shown.

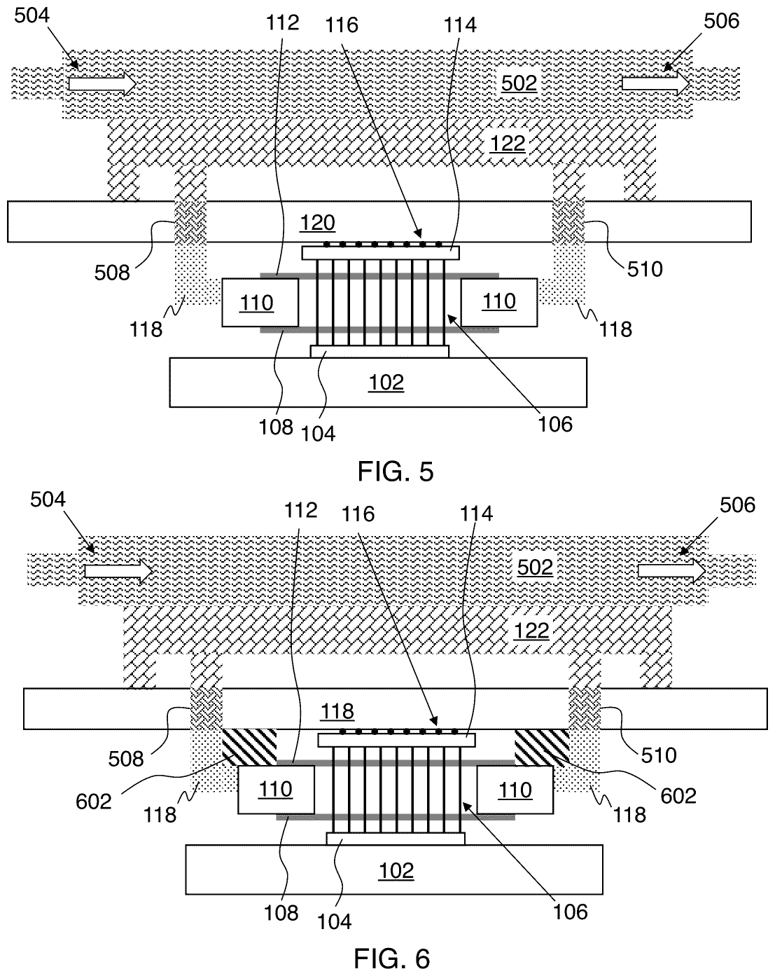

The example of FIG. 5 shows at least one liquid-cooled heat exchanger element 502 disposed on the stiffener 122 and where the at least one heat conduction feature includes at least one solid heat conduction member (508 and 510) in direct thermal contact with the stiffener 122 and in direct thermal contact with the mounting ring 118. Here 504 and 506 schematically show liquid flows to and from heat exchanger element 202, respectively. Heat conduction members 508 and 510 can be made of any thermally conductive material that can be formed into thermal vias that pass through a printed circuit board.

The example of FIG. 6 is similar to the example of FIG. 5, but further includes a thermally conductive filler 602 disposed to increase thermal conduction from the spacer frame 110 to the at least one solid heat conduction member (508, 510).

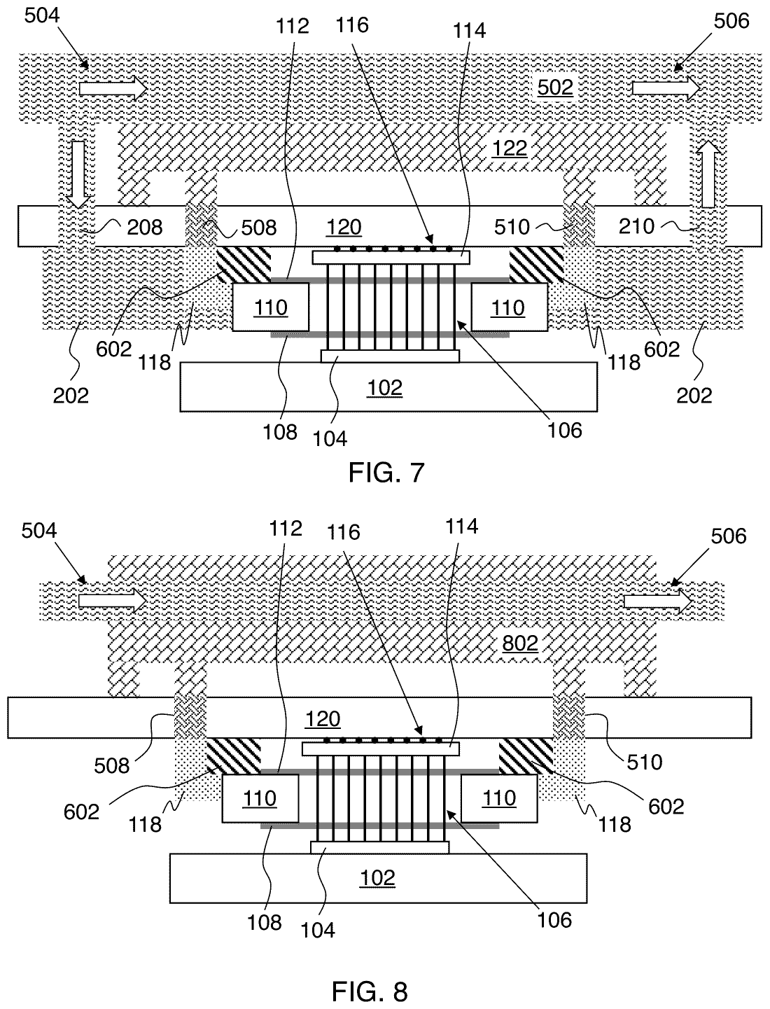

The example of FIG. 7 is a combination of the ideas shows on FIGS. 2 and 6. In this example, the at least one liquid-cooled heat exchanger element includes a first heat exchanger element 502 disposed on the stiffener and a second heat exchanger element 202 disposed on the second surface of the printed circuit board 120. The at least one heat conduction feature includes at least one solid heat conduction member (508, 510) in direct thermal contact with the stiffener 122. The at least one heat conduction feature also includes at least one liquid flow inlet 208 and at least one liquid flow outlet 210 in liquid communication with the second heat exchanger element 202.

The example of FIG. 7 shows a single liquid input and output to the probe head, with a division of liquid flow between heat exchanger elements 202 and 502 occurring within the probe head. It is also possible for these two liquid flow paths to remain separate within the probe head. Practice of the invention does not depend critically on such details of the liquid flow configuration.

The preceding examples show heat exchanger elements configured as separate parts and added to the conventional probe head structure of FIG. 1. It is also possible to integrate a heat exchanger into a probe head part, as in the next two examples.

In the example of FIG. 8, stiffener 802 provides mechanical support for the probe head and is also configured as liquid-cooled heat exchanger element.

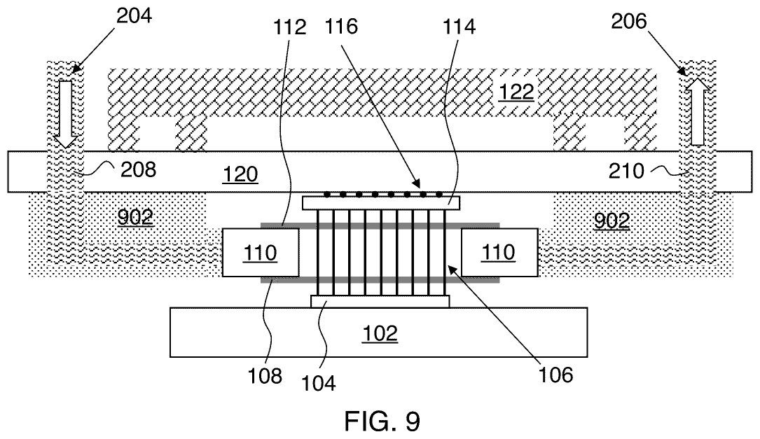

In the example of FIG. 9, mounting ring 902 is configured to attach spacer frame 110 to printed circuit board 120 and is also configured as a liquid-cooled heat exchanger element. Similarly, the spacer frame 110 could also be configured to act as a liquid-cooled heat exchanger element in addition to its usual function of defining the vertical separation of the guide plates.

The preceding examples show vertical probe arrays where vertical motion of the probe tip requires a buckling of the probe along its length, but the ideas of this work are also applicable to probe heads having cantilever probe arrays, where vertical motion of the probe tip requires a sideways motion of a probe member. Thus practice of the invention does not depend critically on the type of probe array used.

1. A probe head for making temporary electrical contact to a device under test, the probe head comprising:
a printed circuit board having opposite first and second surfaces;
a space transformer disposed on the second surface of the printed circuit board;
a probe array disposed on the space transformer, wherein probe tips of the probe array face away from the printed circuit board;
at least one liquid-cooled heat exchanger element for dissipating heat received by the probe head from the device under test; and
at least one heat conduction feature configured to pass through the printed circuit board.

2. The probe head of claim 1, further comprising a stiffener disposed on the first surface of the printed circuit board, wherein the at least one liquid-cooled heat exchanger element is disposed on the stiffener, and wherein the at least one heat conduction feature includes at least one solid heat conduction member in direct thermal contact with the stiffener.

3. The probe head of claim 2, further comprising a probe head assembly including:
guide plates for the probe array;
a spacer frame configured to laterally surround the probe array and configured to define a vertical separation of the guide plates;
and a mounting ring configured to attach the spacer frame to the printed circuit board.

4. The probe head of claim 3, wherein the at least one solid heat conduction member is in direct thermal contact with the mounting ring.

5. The probe head of claim 4, further comprising a thermally conductive filler disposed to increase thermal conduction from the spacer frame to the at least one solid heat conduction member.

6. The probe head of claim 1, wherein the at least one liquid-cooled heat exchanger element is disposed on the second surface of the printed circuit board, and wherein the at least one heat conduction feature includes at least one liquid flow inlet and at least one liquid flow outlet in liquid communication with the at least one liquid-cooled heat exchanger element.

7. The probe head of claim 6, further comprising a probe head assembly including:
guide plates for the probe array;
a spacer frame configured to laterally surround the probe array and configured to define a vertical separation of the guide plates;
and a mounting ring configured to attach the spacer frame to the printed circuit board.

8. The probe head of claim 7, wherein the least one liquid-cooled heat exchanger element is disposed to make direct thermal contact to the mounting ring.

9. The probe head of claim 8, wherein the at least one liquid-cooled heat exchanger element is disposed to make direct thermal contact to the spacer frame.

10. The probe head of claim 1, further comprising a stiffener disposed on the first surface of the printed circuit board, wherein the at least one liquid-cooled heat exchanger element includes a first heat exchanger element disposed on the stiffener and a second heat exchanger element disposed on the second surface of the printed circuit board;
wherein the at least one heat conduction feature includes at least one solid heat conduction member in direct thermal contact with the stiffener;
wherein the at least one heat conduction feature includes at least one liquid flow inlet and at least one liquid flow outlet in liquid communication with the second heat exchanger element.

11. The probe head of claim 10, further comprising a probe head assembly including:
guide plates for the probe array;
a spacer frame configured to laterally surround the probe array and configured to define a vertical separation of the guide plates;
and a mounting ring configured to attach the spacer frame to the printed circuit board.

12. The probe head of claim 11, further comprising a thermally conductive filler disposed to increase thermal conduction from the spacer frame to the at least one solid heat conduction member.

13. The probe head of claim 1, wherein the at least one liquid-cooled heat exchanger element is a distinct part of the probe head.

14. The probe head of claim 1, wherein the at least one liquid-cooled heat exchanger element is integrated with a part of the probe head selected from the group consisting of: stiffener disposed on the first surface of the printed circuit board, spacer frame configured to laterally surround the probe array and configured to define a vertical separation of the guide plates, and mounting ring configured to attach the spacer frame to the printed circuit board.
